(19) United States
(12) Patent Application Publication
(10) Pub. No.: US 2025/0261464 A1
(43) Pub. Date: Aug. 14, 2025

(54) IMAGE SENSOR PIXEL DESIGN

(71) Applicant: Fairchild Imaging, Inc., San Jose, CA (US)

(72) Inventors: Xianmin Yi, Menlo Park, CA (US); Alexander Lu, San Jose, CA (US)

(73) Assignee: Fairchild Imaging, Inc., San Jose, CA (US)

(21) Appl. No.: 18/438,600

(22) Filed: Feb. 12, 2024

(51) Int. Cl. H01L 27/146; H04N 25/772; H04N 25/778

(52) U.S. Cl. CPC H10F 39/8057; H04N 25/772; H04N 25/778

(57) ABSTRACT

An image sensor includes a pixel array across a substrate, with at least one pixel of the array being defined by dielectric walls extending from both the top and bottom surfaces of the substrate. The dielectric walls contact each other within the substrate. The dielectric walls encircle around, or form a perimeter around, a volume of semiconductor material that defines the pixel. In this way, light entering through one end of the pixel is generally confined between the dielectric walls as it traverses through the height of the pixel. By using two different dielectric walls formed from the frontside and backside of the substrate, thicker substrates can be used which increases the quantum efficiency of the pixel.

### BACKGROUND

Image sensors are widely used for a number of different applications across a large portion of the electromagnetic spectrum. Many image sensor designs use an array of sensors to capture light across a given area. Each sensor may be considered a single pixel of the sensor array, with the pixels arranged in any number of rows and columns. Each pixel includes a photodetector as well as a circuit to collect the charge from the photodetector in response to a light impinging on the photodetector. A number of non-trivial issues exist with regard to the design of the sensor circuit to provide both a high dynamic range and a high conversion gain.

### BRIEF DESCRIPTION OF THE DRAWINGS

FIG. 1 is a block diagram of an image sensor that uses a pixel array, in accordance with an embodiment of the present disclosure.

FIG. 2 is a block diagram illustrating components of a single pixel of the pixel array of FIG. 1, in accordance with an embodiment of the present disclosure.

FIG. 3 is a schematic diagram illustrating the single pixel of FIG. 2, in accordance with an embodiment of the present disclosure.

FIG. 4A is a cross-section view of a single pixel, in accordance with an embodiment of the present disclosure.

FIG. 4B is a plan view of the single pixel of FIG. 4A within an array of pixels, in accordance with an embodiment of the present disclosure.

FIG. 4C is a cross-section view of the single pixel from FIG. 4A illustrating an example light path through the pixel, in accordance with an embodiment of the present disclosure.

FIGS. 5A-5F are cross-section views of different stages in a fabrication process to form the pixel of FIG. 4A, in accordance with some embodiments of the present disclosure.

FIG. 6 illustrates an example computing platform that may include the image sensor of FIG. 1, in accordance with an embodiment of the present disclosure.

These and other features of the present embodiments will be understood better by reading the following detailed description, taken together with the figures herein described.

### DETAILED DESCRIPTION

Image sensors are disclosed. In an example, an image sensor includes a pixel array across a substrate, with at least one pixel of the array being defined by dielectric walls extending from both the top and bottom surfaces of the substrate. The dielectric walls contact each other within the substrate, and in some examples, at or near (e.g., within 200 nm) a midpoint along a total thickness of the substrate. The dielectric walls encircle around, or form a perimeter around, a volume of semiconductor material that defines the pixel. In this way, light entering through one end of the pixel is generally confined between the dielectric walls as it traverses through the height of the pixel. By using two different dielectric walls formed from the frontside and backside of the substrate, thicker substrates can be used which increases the quantum efficiency of the pixel. The pixel substrate may include two doped regions stacked over one another, such that a first doped region is adjacent to a first dielectric wall at the top of the substrate and a second doped region is adjacent to a second dielectric wall at the bottom of the substrate. In some examples, a border between the first and second doped regions is at or near (e.g., within 200 nm) of a border between the first dielectric wall and the second dielectric wall. Numerous variations and embodiments will be apparent in light of this disclosure.

### General Overview

As previously noted, there a number of non-trivial issues that remain with respect to designing image sensor circuits, particularly with respect to pixel design. For example, a complementary metal oxide semiconductor (CMOS) image sensor (CIS) includes a pixel array. A given pixel circuit of the array may include a photodetector (e.g., a pixel) coupled to a readout circuit. The pixel itself is formed within a semiconductor substrate and includes some dielectric barrier around a perimeter of the pixel to define the pixel footprint. Light impinging upon a receiving end of the pixel reflects off of the inner walls of the dielectric barrier to remain within the pixel as it traverses through a thickness of the semiconductor substrate towards a gate at a sensing end of the pixel opposite to the receiving end. However, due to practical limitations of semiconductor fabrication, there are limits to the achievable thickness of the pixel substrate, which in turn limits the quantum efficiency (QE) of the pixel. This limitation to the achievable QE is challenging for certain applications, like night vision, where very low amplitudes of light need to be collected and amplified.

Thus, and in accordance with an embodiment of the present disclosure, techniques are disclosed for designing a pixel having a thicker substrate compared to conventional designs by using both frontside and backside dielectric walls. In an example, an image sensor includes an array of pixels across a substrate. A given pixel of the array of pixels may be defined at a location across the substrate using a first dielectric wall around a perimeter of the pixel and extending down into the substrate from a top surface of the substrate and a second dielectric wall around the perimeter of the pixel and extending up into the substrate from a bottom surface of the substrate. The first and second dielectric walls may contact one another to form a combined dielectric wall that is able to extend through a thicker substrate compared to a single frontside dielectric wall or a single backside dielectric wall. In some examples, a total thickness of the substrate may be between about 10 μm and about 20 μm, such as around 12 μm.

According to some embodiments, a doping profile is used within the pixel's semiconductor region that includes a first doped region having n-type dopants over a second doped region having p-type dopants. In some examples, the first doped region is adjacent to the first dielectric wall and the second doped region is adjacent to the second dielectric wall. In some embodiments, a boundary between the first and second dielectric walls is at substantially the same depth (e.g., within 200 nm) beneath the top surface of the substrate as a boundary between the first and second doped regions. The second doped region has a higher concentration of p-type dopants compared to the concentration of n-type dopants in the first doped region. For example, the first doped region may have a concentration of n-type dopants between 1×10¹³ and 1×10¹⁴ cm⁻³ while the second doped region may have a concentration of p-type dopants between 1×10¹⁵ and 1×10¹⁶ cm⁻³. In some embodiments, a dopant gradient is formed between the bottom surface of the substrate and a top surface of the substrate such that the concentration of p-type dopants gradually decreases from the bottom surface of the substrate towards the top surface of the substrate, and the concentration of n-type dopants gradually decreases from the top surface of the substrate towards the bottom surface of the substrate.

The sensor array of pixels may be, for example, a CMOS image sensor (CIS) array or a charge coupled device (CCD) array, or a hybrid CMOS-CCD array having a CMOS readout circuit coupled with a CCD sensor. Other pixel-based imaging arrays may also benefit.

According to an example embodiment, an image sensor includes a semiconductor substrate having a given thickness between a top surface and a bottom surface of the semiconductor substrate and a plurality of pixels arranged across the substrate. A pixel of the plurality of pixels includes a first dielectric wall arranged around a perimeter of the pixel and a second dielectric wall arranged around the perimeter of the pixel and below the first dielectric wall. The first dielectric wall extends into the semiconductor substrate at a first distance beneath the top surface of the semiconductor substrate and the second dielectric wall extends into the semiconductor substrate at a second distance above the bottom surface of the semiconductor substrate. A sum of the first distance and the second distance is equal to the given thickness of the semiconductor substrate.

According to another example embodiment, an image sensor includes a pixel array having at least one column of addressable pixels, a column amplifier coupled to the at least one column of addressable pixels, an analog-to-digital converter (ADC) coupled to the column amplifier, and a processor coupled to the ADC. The at least one column of addressable pixels includes a pixel that has a first dielectric wall arranged around a perimeter of the pixel and a second dielectric wall arranged around the perimeter of the pixel and below the first dielectric wall. The first dielectric wall extends into a semiconductor substrate at a first distance beneath a top surface of the semiconductor substrate and the second dielectric wall extends into the semiconductor substrate at a second distance above a bottom surface of the semiconductor substrate. A top surface of the second dielectric wall contacts a bottom surface of the first dielectric wall.

According to another example embodiment, a pixel of a pixel array within a CMOS image sensor includes a first semiconductor region having a first concentration of n-type dopants, a second semiconductor region beneath the first semiconductor region and having a second concentration of p-type dopants, a first dielectric wall arranged around a perimeter of the pixel and extending through a thickness of the first semiconductor region, and a second dielectric wall arranged around the perimeter of the pixel and extending through a thickness of the second semiconductor region. The second dielectric wall contacts the first dielectric wall.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### System Architecture

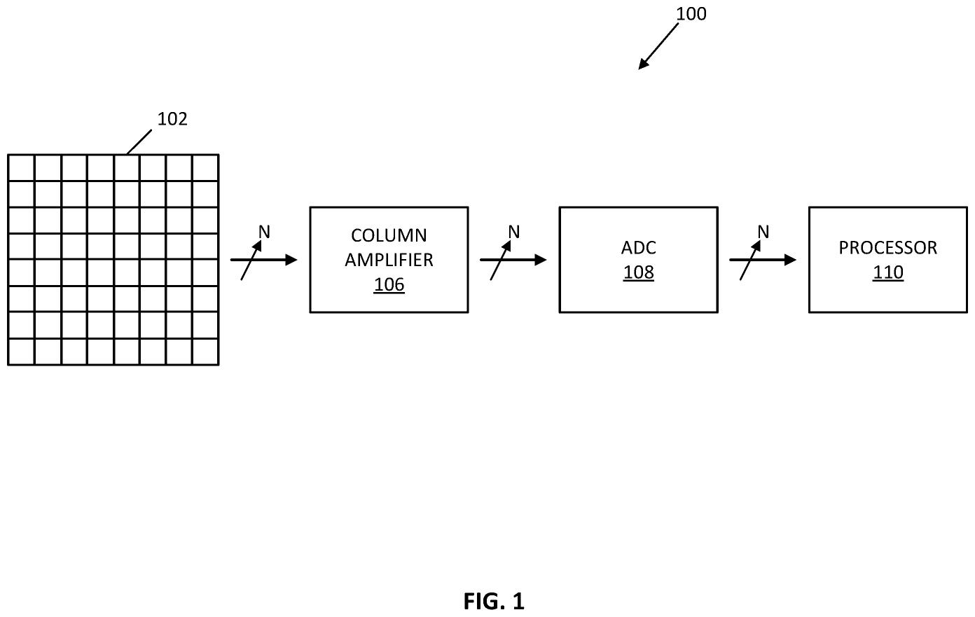

FIG. 1 is a block diagram of an example image sensor 100, according to some embodiments. Image sensor 100 may represent or be an integral part of imaging sensor device (e.g., CIS device, CCD device, or a hybrid CMOS-CCD device). In some embodiments, image sensor 100 may be configured for capturing different portions of the electromagnetic spectrum, such as visible light, ultraviolet radiation, infrared radiation, or x-rays, to name a few examples. Image sensor 100 may include a pixel array 102, a column amplifier 106, an ADC 108, and a processor 110. Each of the illustrated components may be included together on same printed circuit board (PCB) or together in a single chip package (e.g., a system-in-package or system-on-chip). In some other embodiments, any one or more of the elements may be provided in a separate chip package and/or on separate PCBs.

According to some embodiments, pixel array 102 includes a plurality of pixels arranged in a row-column format. Each pixel of pixel array 102 may have a similar architecture that includes a photodetector and a readout circuit. The photo detection area of each pixel on which incident radiation may impinge may vary from one embodiment to the next, but in some example cases has a physical size of around 1 μm×1 μm up to around 15μm×15 μm. Likewise, the shape and lensing (if present) of the photo detection area (e.g., photo diode) can also vary from one example to the next, depending on factors such as desired fill factor of the array. According to some embodiments, each row of pixels may be coupled together via a common (shared) row-select line (e.g., a wordline), to provide separately addressable rows of pixels. The term pixel may refer to the photodetection area within a semiconductor substrate coupled to a respective readout circuit, or it may refer to only the photodetection area within the semiconductor substrate (e.g., excluding the readout circuit).

According to some embodiments, the outputs from N different columns of pixels are received by column amplifier 106. According to some embodiments, column amplifier 106 represents N separate column amplifiers with a given column amplifier configured to receive the output from a corresponding column of pixels from pixel array 102. In this way, a given row of pixels from pixel array 102 can be selected via a row-select line and simultaneously read out via the N column amplifiers 106. According to some embodiments, column amplifier 106 may include any type of amplifier configuration, such as any number of source follower FETs or operational amplifiers. In some embodiments, a single column amplifier 106 may be used in conjunction with a multiplexer to receive each of the N column outputs from pixel array 102.

According to some embodiments, the output(s) from column amplifier 106 is/are received by ADC 108. As noted above, ADC 108 may represent N different ADCs with a given ADC configured to receive the output from a corresponding column amplifier 106. ADC 108 may be any known type of ADC without limitation.

Processor 110 may be configured to receive the digitized signal from ADC 108 (or N digitized signals across N ADCs) and perform any number of operations with the signal(s). For example, processor 110 may receive the signal data from a given row of pixels of pixel array 102 and use the signal data to create an image or a portion of an image captured via pixel array 102. As used herein, the term “processor” may refer to any device or portion of a device that processes electronic data from registers and/or memory to transform that electronic data into other electronic data that may be stored in registers and/or memory. Processor 110 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, custom-built semiconductor, or any other suitable processing devices.

### Pixel Design

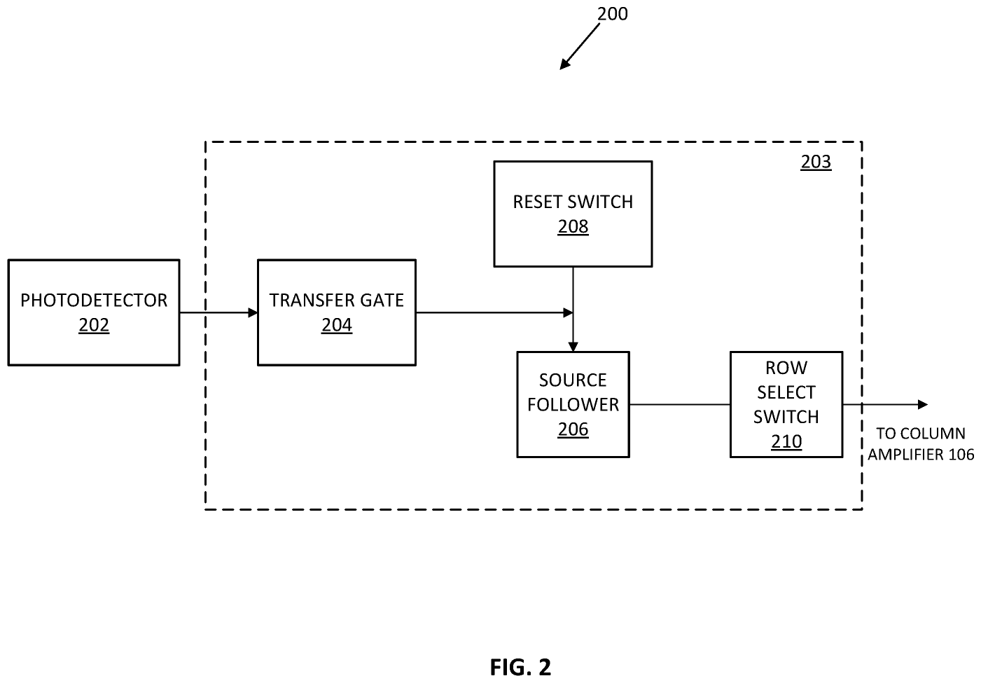

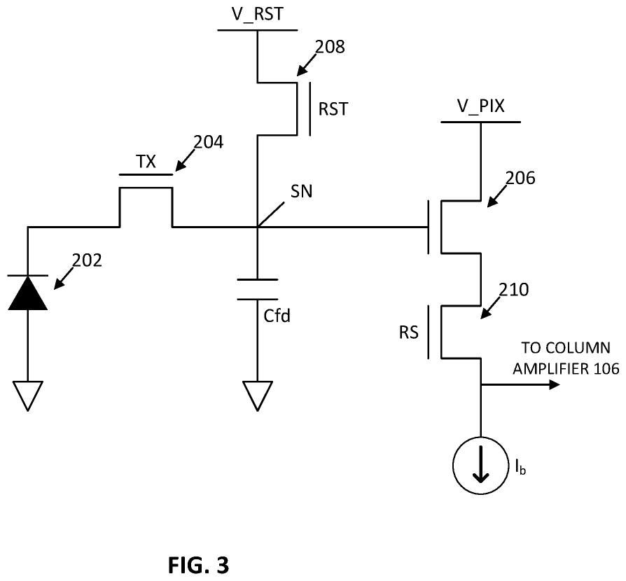

FIG. 2 illustrates a block diagram of a pixel 200 from pixel array 102 that includes a photodetector 202 and a readout circuit 203, according to some embodiments. FIG. 3 illustrates an example circuit schematic of the pixel block diagram from FIG. 2. Photodetector 202 may include any type of photosensitive design, such as a PN diode, within a semiconductor substrate (e.g., a silicon substrate).

According to some embodiments, readout circuit 203 includes a transfer gate 204 coupled to an output of photodetector 202. As described above, the active area of the photodetector 202 (e.g., the area which is sensitive to impinging light and generates a corresponding signal based on intensity of that light), as well as any lensing, can vary depending on the given application. Transfer gate 204 acts like a gatekeeper to the charge generated by photodetector 202 in response to a light input. In some embodiments, transfer gate 204 may include a single field effect transistor (FET), such as a p-doped or n-doped metal oxide semiconductor device (PMOS or NMOS), or any number of FETs that carry out a similar function.

Transfer gate 204 is configured to allow charge from photodetector 202 to pass on to a storage node SN coupled to a gate of a source follower 206. The charge may be stored across one or more capacitors coupled to storage node SN (e.g., Cfd), according to some embodiments. Source follower 206 may be implemented, for example, as a single source-follower NMOS or PMOS device, or as an operational amplifier. Source follower 206 may be powered, for example, via rail power V_PIX between about 2 V and about 2.5 V or some other suitable rail voltage. According to some embodiments, a reset switch 208 is also coupled to storage node SN (and the gate of source follower 206). Reset switch 208 may include a single field effect transistor (FET), such as a p-doped or n-doped metal oxide semiconductor device (PMOS or NMOS), or any number of FETs that carry out a similar function. A reset signal (RST) may be applied to a gate of reset switch 208 to apply a reset voltage (V_RST) to the storage node SN and clear it of any accumulated charge.

According to some embodiments, source follower 206 converts the stored charge from storage node SN into a corresponding photocurrent that is sent on to column amplifier 106 in response to the assertion of a row select signal RS at a row select switch 210. Row select switch 210 may have a gate or select input that is coupled to a common row-line (e.g., a wordline) with other pixels of the same row. Accordingly, when the current row is activated to read out from, row select switch 210 is activated and turned on to read out the output current to column amplifier 106. When the current row is not selected, row select switch 210 is not active and no signal is read out to column amplifier 106. Row select switch 210 may be implemented as an NMOS or PMOS device with the row-line RS coupled to the gate of the NMOS or PMOS device.

### Source Follower Design

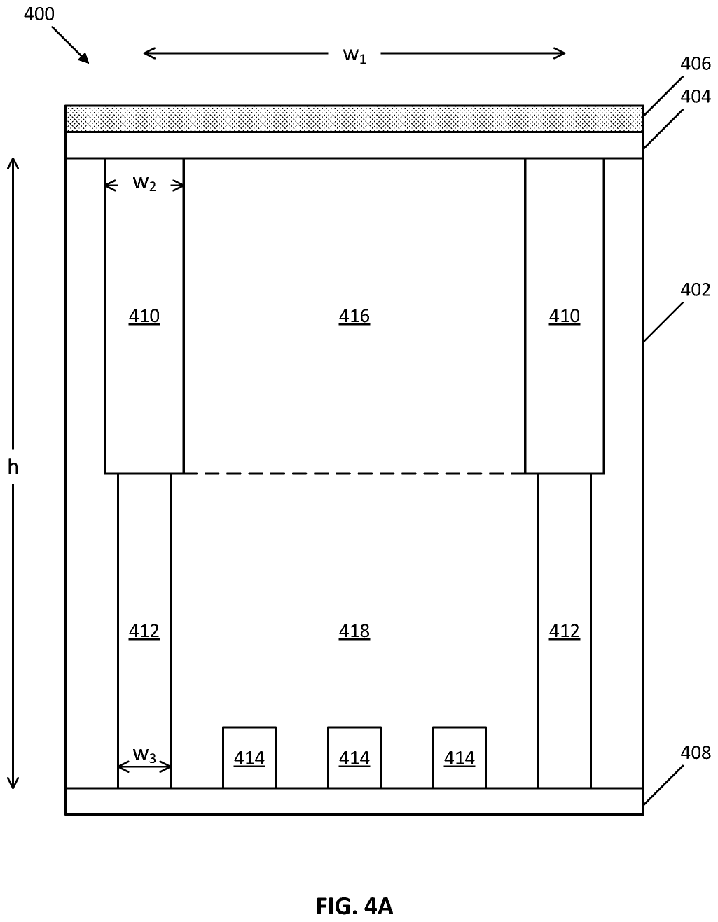

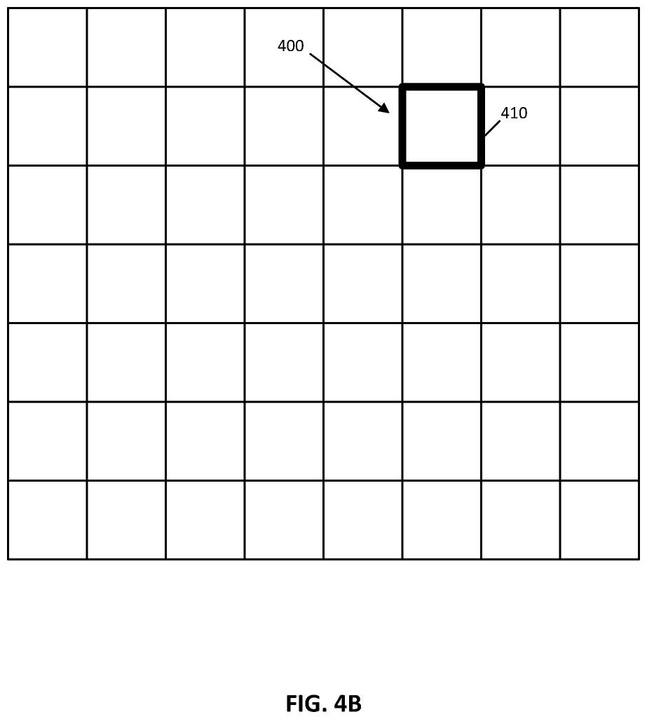

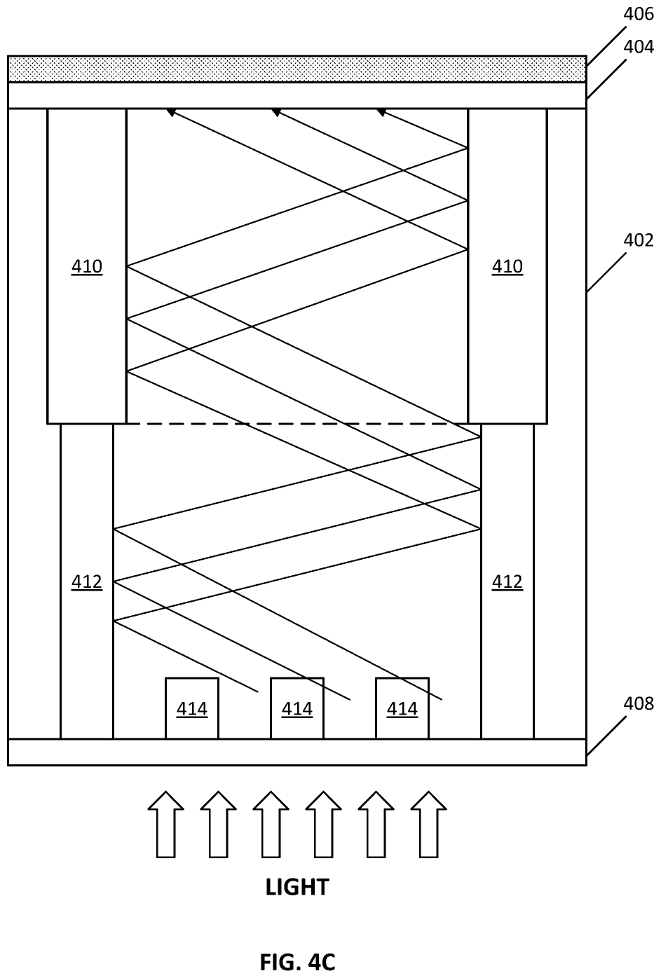

FIG. 4A illustrates an example cross-section of a single photodetector (herein referred to as a pixel 400). Pixel 400 includes a PN junction that is formed within a semiconductor substrate 402. Substrate 402 may be any suitable semiconductor material used for light conversion, such as silicon, or III-V materials like indium phosphide or gallium arsenide. According to some embodiments, substrate 402 has a total thickness or height h between about 10 μm and about 20 μm, such as around 12 μm. Substrate 402 may also act as a semiconductor layer that includes other material layers on its bottom and/or top surfaces.

For instance, in the example embodiment shown in FIG. 4A, a first dielectric layer 404 is disposed on a top surface of substrate 402. First dielectric layer 404 may represent one or more dielectric layers used to trap charge between substrate 402 and a gate 406. In some such embodiments, first dielectric layer 404 includes a layer of silicon dioxide with a thickness between 50 nm and 200 nm. Gate 406 may represent a layer of any suitable conductive material on first dielectric layer 404. In some examples, gate 406 includes any of polysilicon, tungsten, cobalt, or copper. In some such example embodiments, a second dielectric layer 408 is present on a bottom surface of substrate 402. Similar to first dielectric layer 404, second dielectric layer 408 may represent any number of layers of different dielectric materials. In some such examples, second dielectric layer 408 includes a layer of silicon dioxide with a thickness between about 50 nm and about 150 nm.

According to some embodiments, the pixel area is defined by dielectric walls that extend along the perimeter of the pixel. In the illustrated example of FIG. 4A, a first dielectric wall 410 extends into substrate 402 from a top surface of substrate 402 and a second dielectric wall 412 extends into substrate 402 from a bottom surface of substrate 402. According to some such embodiments, the first and second dielectric walls 410,412 contact each other at or near a midpoint of substrate 402 to form combined dielectric structures that extend through the entire thickness of substrate 402. In other words, a sum of a height of first dielectric wall 410 and a height of second dielectric wall 412 is equal to a total height h of substrate 402. In the example shown, the height of first dielectric wall 410 and the height of second dielectric wall 412 are about equal (e.g., height of each wall 410,412 is between about 5 μm and about 10 μm, such as around 6 μm), but in other examples the heights of walls 410,412 may not be equal (e.g., where dielectric wall 410 is taller than dielectric wall 412, or vice-versa).

According to some embodiments, the dielectric walls define each pixel within the array. FIG. 4B illustrates a plan view across a pixel array showing how first dielectric walls 410 extend around an entire perimeter of pixel 400. Each other pixel of the array may similarly include dielectric walls around their perimeter to define their pixel area within the substrate. The dielectric walls reflect the light collected at the bottom end of a given pixel to contain the light within the given pixel as it travels upwards towards the gate of the given pixel. Although each pixel of the pixel array is shown as having a square shaped perimeter, any other shapes may be used as well, such as rectangular shapes, circular shapes, or rounded square or rectangular shapes.

Turning back to FIG. 4A, the total width w₁ of pixel 400 may be defined as a distance between opposing sides of first dielectric wall 410, as measured from the center of first dielectric wall 410. According to some embodiments, width w₁ is between 8 μm and 12 μm, such as around 10 μm. A width w₂ of first dielectric wall 410 along the top surface of substrate 402 may be, for example, between about 0.3 μm and 1 μm. The width of first dielectric wall 410 may decrease slightly (e.g., inwardly taper) along its height from its top surface towards its bottom surface due to the fabrication process. A width w₃ of second dielectric wall 412 along the bottom surface of substrate 402 may be, for example, between about 0.1 μm and 0.5 μm. The width of second dielectric wall 412 may decrease slightly (e.g., inwardly taper) along its height from its bottom surface towards its top surface due to the fabrication process. According to some embodiments, second dielectric wall 412 is thinner compared to first dielectric wall 410 to assist in the fabrication of second dielectric wall 412. As will be discussed in more detail herein, first dielectric wall 410 may act as an etch stop for the formation of second dielectric wall 412.

Each of first dielectric wall 410 and second dielectric wall 412 may include any number of dielectric materials. In some examples, first dielectric wall 410 and second dielectric wall 412 each include a core dielectric material and a dielectric liner along the outside edges of the structure (e.g., between the core dielectric material and substrate 402). The dielectric core may include any suitable dielectric material, such as silicon dioxide. In some embodiments, the dielectric liner may represent any number of dielectric layers that promote reflection of light that is desired to be captured by the image sensor. For example, when capturing infrared light having wavelengths between 0.8 μm and 2 μm the dielectric liner may include a layer of hafnium oxide or aluminum oxide to enhance the reflectivity of the surface to that range of the electromagnetic spectrum.

According to some embodiments, pixel 400 also includes grating elements 414 provided through the bottom surface of substrate 402 between second dielectric wall 412. Grating elements 414 may include any suitable dielectric material, and may have a similar or the same dielectric structure as second dielectric wall 412. According to some embodiments, each grating element 414 has a height that is less than the height of second dielectric wall 412. For example, grating elements 414 may have a height between about 0.3 μm and 0.5 μm. Any number of equally spaced grating elements 414 may be provided in a given pixel 400 in order to refract the light received at the bottom surface of substrate 402. FIG. 4C illustrates an example of light being collected at the bottom surface of the pixel. Grating elements 414 bend and/or refract the received light such that it bounces between first dielectric wall 410 and second dielectric wall 412 on its way towards gate 406. Refracting the light effectively increases the pathlength of the light through substrate 402 and thus increases the chance of forming electron-hole pairs within the PN junction.

Returning to FIG. 4A, the PN junction of the photodetector is represented by a first doped region 416 over a second doped region 418. Accordingly, substrate 402 includes two doped portions stacked on each other. According to some embodiments, first doped region 416 includes n-type dopants (e.g., arsenic or phosphorus) and second doped region 418 includes p-type dopants (e.g., boron). Second doped region 418 may have a higher dopant concentration of p-type dopants compared to the dopant concentration of n-type dopants in first doped region 416. For example, first doped region 416 may include a n-type dopant concentration between 1×10¹³ and 1×10¹⁴ cm⁻³ and second doped region 418 may include a p-type dopant concentration between 1×10¹⁵ and 1×10¹⁶ cm⁻³.

According to some embodiments, first doped region 416 may have substantially the same thickness (e.g., within 200 nm) as second doped region 418. Accordingly, first doped region 416 and second doped region 418 may each have a thickness between about 5 μm and about 10 μm, such as around 6 μm. In some embodiments, a boundary (illustrated as a dashed line) between first doped region 416 and second doped region 418 represents a step change in the dopant type and dopant concentration between the two regions. However, in some embodiments, a gradient dopant profile is used such that the concentration of n-type dopants in first doped region 416 is highest at the top surface of substrate 402 and decreases gradually moving downwards towards the boundary between first doped region 416 and second doped region 418. Similarly, the concentration of p-type dopants in second doped region 418 may be highest at the bottom surface of substrate 402 and decreases gradually moving upwards towards the boundary between first doped region 416 and second doped region 418. In such examples, the transition between first doped region 416 and second doped region 418 is not as sharp.

According to some embodiments, the boundary between first doped region 416 and second doped region 418 may be at substantially the same distance below the top surface of substrate 402 (or above the bottom surface of substrate 402) as the boundary between first dielectric wall 410 and second dielectric wall 412. In some examples, the boundary between first doped region 416 and second doped region 418 is within 200 nm above or below the boundary between first dielectric wall 410 and second dielectric wall 412.

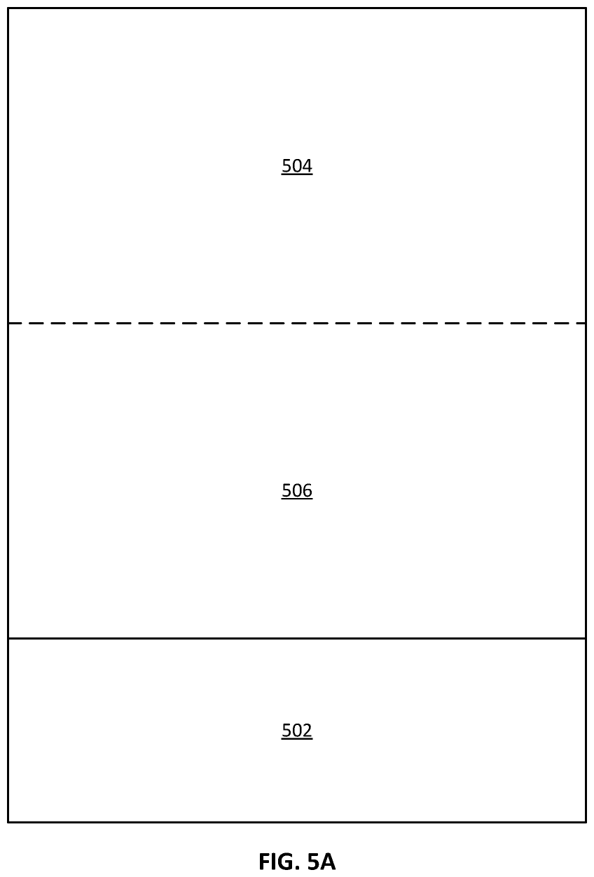

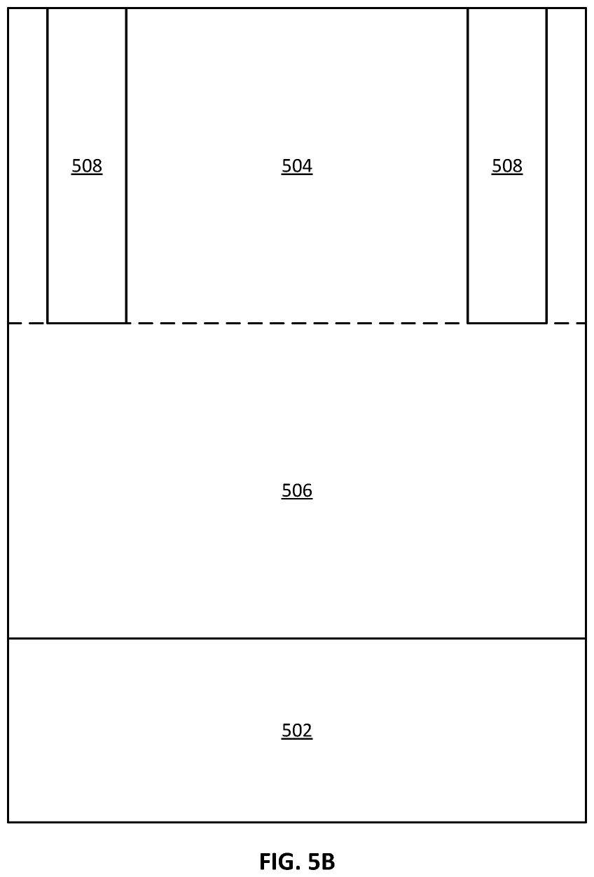

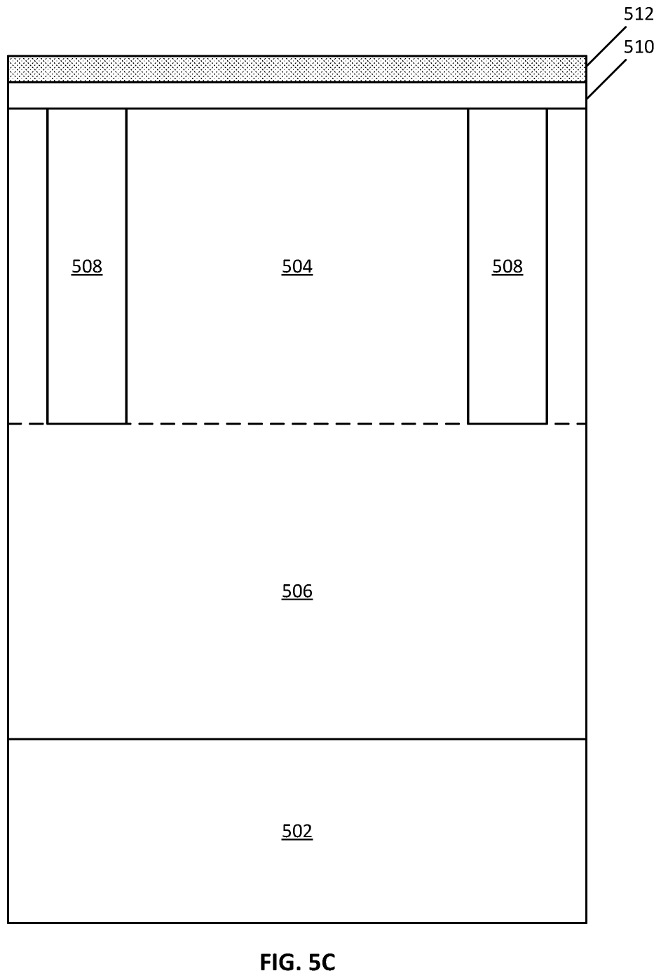

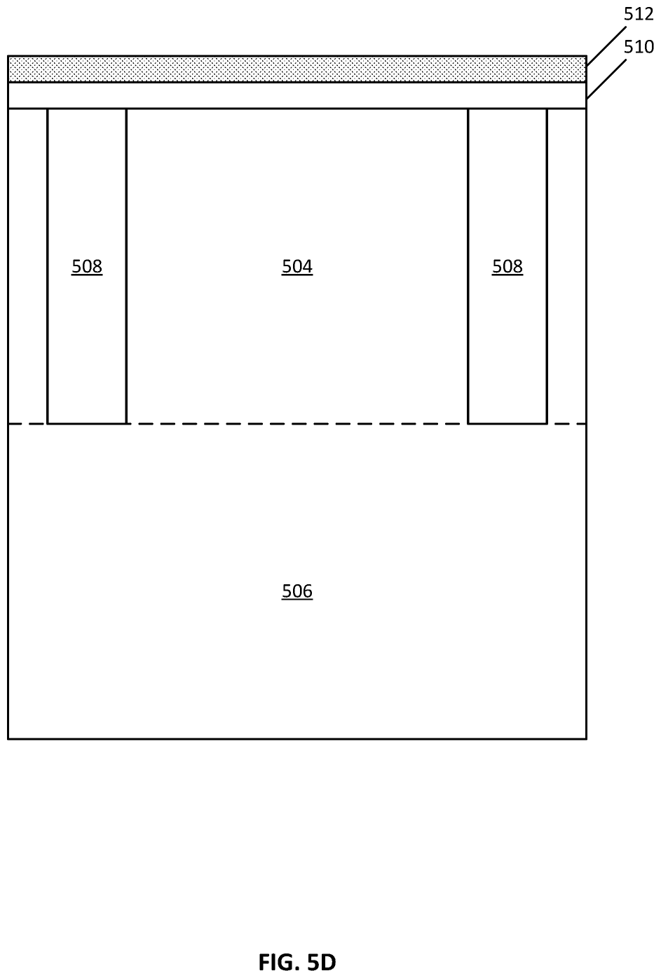

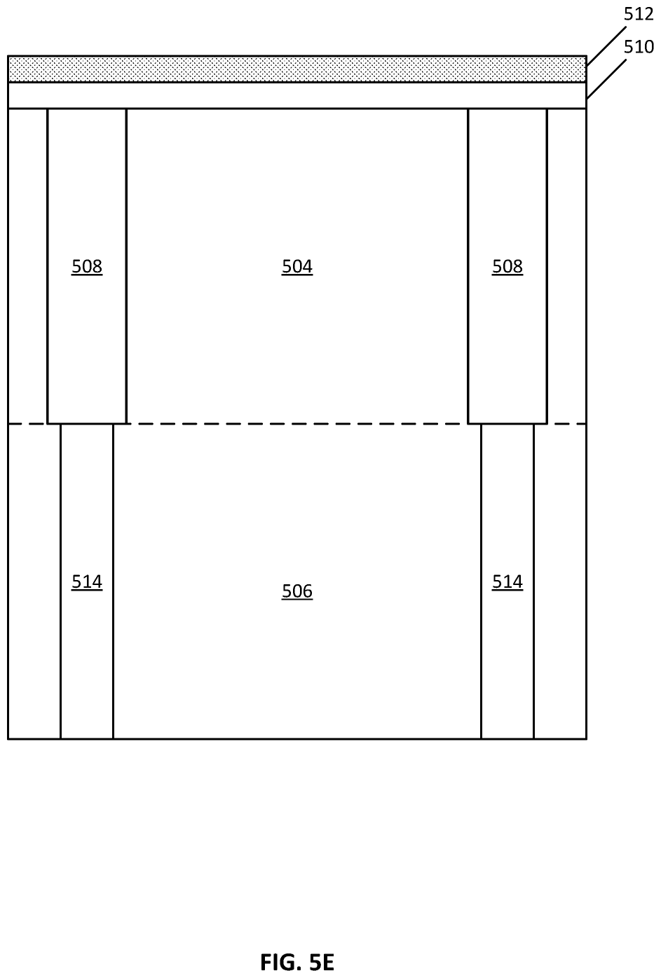

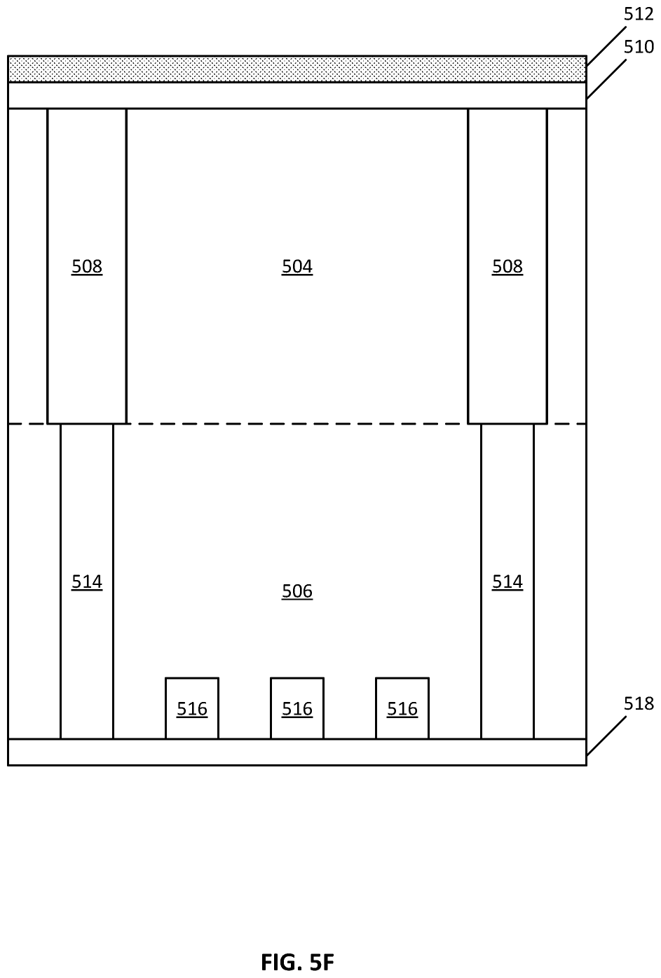

FIGS. 5A-5F include cross-sectional views that collectively illustrate an example process for forming a single pixel of a pixel array, in accordance with an embodiment of the present disclosure. Accordingly, the process shown here to form one pixel may be simultaneously performed across a given substrate to form any number of other pixels in the array. Each of the figures shows an example structure that results from the process flow up to that point in time, so the depicted structure evolves as the process flow continues, culminating in the structure shown in FIG. 5F, which is similar to the example structure shown in FIG. 4A. Such a structure may be part of an overall integrated circuit (e.g., such as a photonic integrated circuit) or system-on-chip that includes, for example, image processing circuitry. Thus, the illustrated photodetector structure may be part of a larger integrated circuit that includes other integrated circuitry not depicted. Example materials and process parameters are given, but the present disclosure is not intended to be limited to any specific such materials or parameters, as will be appreciated.

FIG. 5A illustrates a substrate 502 along with a first doped semiconductor layer 504 over a second doped semiconductor layer 506, according to some embodiments. Substrate 502 may be a silicon substrate or any other suitable semiconductor substrate. According to some embodiments, each of first doped semiconductor layer 504 and second doped semiconductor layer 506 are epitaxially grown over substrate 502 to form high-quality layers. In some examples, second doped semiconductor layer 506 is epitaxially grown on a top surface of substrate 502 while first doped semiconductor layer 504 is epitaxially grown on a top surface of second doped semiconductor layer 506. In other examples, each of first doped semiconductor layer 504 and second doped semiconductor layer 506 are deposited over substrate 502 using chemical vapor deposition (CVD) or plasma enhanced chemical vapor deposition (PECVD). Each of first doped semiconductor layer 504 and second doped semiconductor layer 506 may have substantially the same thickness, such as between 5 μm and 10 μm. The combined structure of first doped semiconductor layer 504 and second doped semiconductor layer 506 will ultimately serve as the substrate for the pixel, according to some embodiments.

First doped semiconductor layer 504 may include silicon with arsenic or phosphorus dopants (n-type). According to some embodiments, first doped semiconductor layer 504 includes a concentration of n-type dopants between 1×10¹³ and 1×10¹⁴ cm⁻³. Second doped semiconductor layer 506 may include silicon with boron dopants (p-type). According to some embodiments, second doped semiconductor layer 506 includes a concentration of p-type dopants between 1×10¹⁵ and 1×10¹⁶ cm⁻³. The dopant concentrations of each of first doped semiconductor layer 504 and second doped semiconductor layer 506 may be substantially consistent throughout an entire thickness of the corresponding layer (exhibiting a sharp step change across the boundary between layers). In some embodiments, the dopant concentrations of first doped semiconductor layer 504 and/or second doped semiconductor layer 506 has a gradient profile across the thickness of the corresponding layer. For example, first doped semiconductor layer 504 may have a highest n-type dopant concentration at its top surface that decreases to a lowest n-type dopant concentration at its bottom surface (e.g., at the interface between first doped semiconductor layer 504 and second doped semiconductor layer 506) while second doped semiconductor layer 506 may have a highest p-type dopant concentration at its bottom surface that decreases to a lowest p-type dopant concentration at its top surface. Other doping profiles may be used depending on the application.

FIG. 5B depicts the cross-section view of the structure shown in FIG. 5A, following the formation of a first dielectric wall 508 through at least a portion of the thickness of first doped semiconductor layer 504, according to some embodiments. As discussed above, first dielectric wall 508 wraps around a perimeter of the pixel to constrain the pixel footprint. A trench is first formed through a thickness of first doped semiconductor layer 504 using a reactive ion etching (RIE) process. According to some embodiments, the depth of the trench is substantially equal to the height of first doped semiconductor layer 504. In some examples, the change in dopant type between first doped semiconductor layer 504 and second doped semiconductor layer 506 can be determined via an analysis of the material being removed during the etch and used to determine that the trench has reached the top of second doped semiconductor layer 506. This information may be used to stop the etching process.

Once the trench has been formed, it may be filled with one or more dielectric materials to form first dielectric wall 508. As discussed above, first dielectric wall 508 may include a dielectric core and a dielectric liner. According to some embodiments, the dielectric liner is formed first along the inner surfaces of the trench on first doped semiconductor layer 504. The dielectric liner may include a layer of hafnium oxide or aluminum oxide and may be deposited using CVD or atomic layer deposition (ALD) to provide conformal coverage within the trench. A remainder of the trench may be filled with the dielectric core to complete the formation of first dielectric wall 508. Dielectric core may be any suitable dielectric material, such as silicon dioxide. First dielectric wall 508 may have a height between about 5 μm and about 10 μm (e.g., substantially the same as the height of first doped semiconductor layer 504).

FIG. 5C depicts the cross-section view of the structure shown in FIG. 5B, following the formation of a first dielectric layer 510 on a top surface of first doped semiconductor layer 504 and a gate 512 over first dielectric layer 510, according to some embodiments. First dielectric layer 510 may represent any number of dielectric layers and may include at least one layer of silicon dioxide. First dielectric layer 510 may have a thickness between about 50 nm and 200 nm. Gate 406 may represent a layer of any suitable conductive material on first dielectric layer 404. In some examples, gate 406 includes any of polysilicon, tungsten, cobalt, or copper.

Any other front-side processing would also be performed across the structure. For example, any semiconductor devices and front-side interconnects to those devices would be formed to provide connections to the various elements across the structure. Interconnects may also be formed to make electrical connection to gate 512.

FIG. 5D depicts the cross-section view of the structure shown in FIG. 5C following the removal of substrate 502 from the backside to expose a bottom surface of second doped semiconductor layer 506, according to some embodiments. Substrate 502 may be removed using any number of different methods including polishing using chemical mechanical polishing (CMP), grinding, or etching. In some embodiments, an etch stop layer may exist between substrate 502 and second doped semiconductor layer 506 to halt or substantially slow any etching or polishing process used to remove substrate 502. The etch stop layer may then remain on the bottom surface of second doped semiconductor layer 506 or may be removed. In one example, a layer of silicon dioxide may be used as an etch stop layer between substrate 502 and second doped semiconductor layer 506. Note that following the removal of substrate 502, the combination of first doped semiconductor layer 504 and second doped semiconductor layer 506 may be referred to as the substrate. As such, the top surface of first doped semiconductor layer 504 may be considered the top surface of the substrate and the bottom surface of second doped semiconductor layer 506 may be considered the bottom surface of the substrate.

FIG. 5E depicts the cross-section view of the structure shown in FIG. 5D following the formation of a second dielectric wall 514 through at least a portion of the thickness of second doped semiconductor layer 506, according to some embodiments. Like first dielectric wall 508, second dielectric wall 514 wraps around the perimeter of the pixel to constrain the pixel footprint. The formation of second dielectric wall 514 is very similar to that described above for first dielectric wall 508. Accordingly, a trench is first formed through a thickness of second doped semiconductor layer 506 from the backside of the structure using an RIE process. According to some embodiments, the depth of the trench is substantially equal to the height of second doped semiconductor layer 506. According to some embodiments, the etching process may continue through second doped semiconductor layer 506 until the bottom surface of first dielectric wall 508 is exposed. In this way, first dielectric wall 508 may act as an etch stop for the trench used to define the location of second dielectric wall 514. In some examples, a width of the backside trench is thinner compared to a width of first dielectric wall 508 to provide some alignment tolerance of the trench with first dielectric wall 508.

Just as discussed above with regards to first dielectric wall 508, any number of different dielectric materials may be deposited within the backside trench to form second dielectric wall 514. Accordingly, second dielectric wall 514 may also include a dielectric core and a dielectric liner that may be substantially the same materials as those used for first dielectric wall 508. Second dielectric wall 514 may have a height between about 5 μm and about 10 μm (e.g., substantially the same as the height of second doped semiconductor layer 506).

FIG. 5F depicts the cross-section view of the structure shown in FIG. 5E following the formation of grating elements 516 and a second dielectric layer 518 along a bottom surface of second doped semiconductor layer 506, according to some embodiments. As discussed above, grating elements include periodically spaced dielectric structures used to refract light entering through the bottom surface of second doped semiconductor layer 506. The formation of such elements may be similar to that of forming the dielectric walls where any number of periodically spaced trenches are formed from the backside of the substrate (e.g., bottom surface of second doped semiconductor layer 506) using RIE and subsequently filled with any number of dielectric materials.

Second dielectric layer 518 may represent any number of dielectric layers. In one example, second dielectric layer 518 includes a layer of silicon dioxide with a thickness of around 100 nm. In some embodiments, second dielectric layer 518 represents an etch stop layer that remains after the removal of substrate 502. In some embodiments, second dielectric layer 518 represents the buried oxide layer of a silicon-on-insulator (SOI) substrate.

By forming dielectric walls through both the frontside and backside of the substrate (that meet together at or near the midpoint of the substrate), the total height of the substrate can be increased compared to designs that only form a single dielectric wall. The increased substrate height increases the pathlength of light through the substrate, thus increasing the generation of electron-hole pairs, thus increasing the QE of the pixel.

### Example Computing Platform

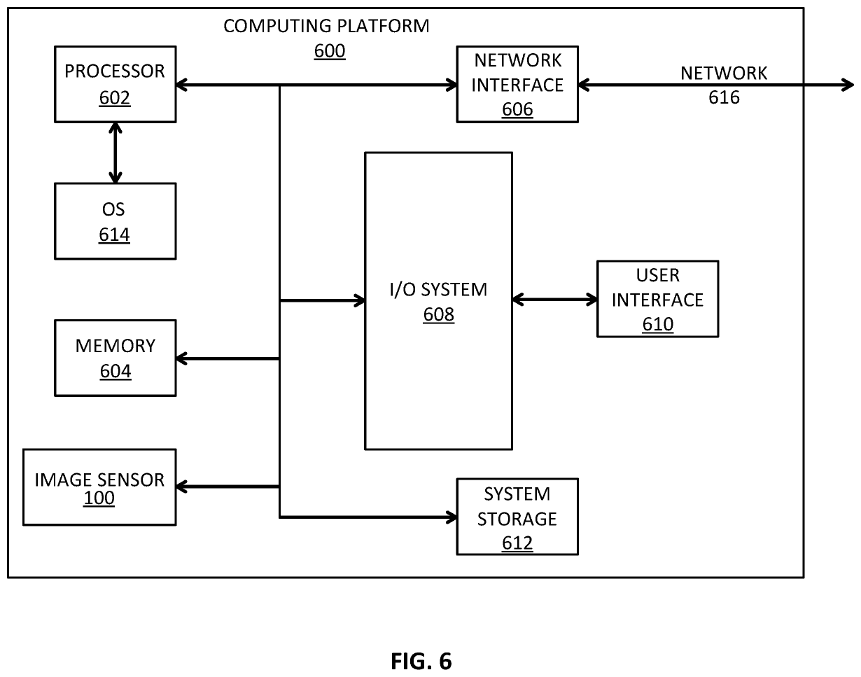

FIG. 6 illustrates an example computing platform 600 that interfaces with image sensor 100, configured in accordance with certain embodiments of the present disclosure. In some embodiments, computing platform 600 may host, or otherwise be incorporated into a personal computer, workstation, server system, laptop computer, ultra-laptop computer, tablet, touchpad, portable computer, handheld computer, palmtop computer, personal digital assistant (PDA), cellular telephone, combination cellular telephone and PDA, smart device (for example, smartphone or smart tablet), mobile internet device (MID), messaging device, data communication device, imaging device, wearable device, embedded system, and so forth. Any combination of different devices may be used in certain embodiments.

In some embodiments, computing platform 600 may comprise any combination of a processor 602, a memory 604, image sensor 100, a network interface 606, an input/output (I/O) system 608, a user interface 610, and a storage system 612. In some embodiments, one or more components of image sensor 100 are implemented as part of processor 602. As can be further seen, a bus and/or interconnect is also provided to allow for communication between the various components listed above and/or other components not shown. Computing platform 600 can be coupled to a network 616 through network interface 606 to allow for communications with other computing devices, platforms, or resources. Other componentry and functionality not reflected in the block diagram of FIG. 6 will be apparent in light of this disclosure, and it will be appreciated that other embodiments are not limited to any particular hardware configuration.

Processor 602 can be any suitable processor and may include one or more coprocessors or controllers to assist in control and processing operations associated with computing platform 600. In some embodiments, processor 602 may be implemented as any number of processor cores. The processor (or processor cores) may be any type of processor, such as, for example, a micro-processor, an embedded processor, a digital signal processor (DSP), a graphics processor (GPU), a network processor, a field programmable gate array or other device configured to execute code. The processors may be multithreaded cores in that they may include more than one hardware thread context (or “logical processor”) per core.

Memory 604 can be implemented using any suitable type of digital storage including, for example, flash memory and/or random-access memory (RAM). In some embodiments, memory 604 may include various layers of memory hierarchy and/or memory caches as are known to those of skill in the art. Memory 604 may be implemented as a volatile memory device such as, but not limited to, a RAM, dynamic RAM (DRAM), or static RAM (SRAM) device. Storage system 612 may be implemented as a non-volatile storage device such as, but not limited to, one or more of a hard disk drive (HDD), a solid-state drive (SSD), a universal serial bus (USB) drive, an optical disk drive, tape drive, an internal storage device, an attached storage device, flash memory, battery backed-up synchronous DRAM (SDRAM), and/or a network accessible storage device. In some embodiments, storage system 612 may comprise technology to increase the storage performance enhanced protection for valuable digital media when multiple hard drives are included.

Processor 602 may be configured to execute an Operating System (OS) 614 which may comprise any suitable operating system, such as Google Android (Google Inc., Mountain View, CA), Microsoft Windows (Microsoft Corp., Redmond, WA), Apple OS X (Apple Inc., Cupertino, CA), Linux, or a real-time operating system (RTOS). As will be appreciated in light of this disclosure, the techniques provided herein can be implemented without regard to the particular operating system provided in conjunction with computing platform 600, and therefore may also be implemented using any suitable existing or subsequently developed platform.

Network interface 606 can be any appropriate network chip or chipset which allows for wired and/or wireless connection between other components of computing platform 600 and/or network 616, thereby enabling computing platform 600 to communicate with other local and/or remote computing systems, servers, cloud-based servers, and/or other resources. Wired communication may conform to existing (or yet to be developed) standards, such as, for example, Ethernet. Wireless communication may conform to existing (or yet to be developed) standards, such as, for example, cellular communications including LTE (Long Term Evolution), Wireless Fidelity (Wi-Fi), Bluetooth, and/or Near Field Communication (NFC). Exemplary wireless networks include, but are not limited to, wireless local area networks, wireless personal area networks, wireless metropolitan area networks, cellular networks, and satellite networks.

I/O system 608 may be configured to interface between various I/O devices and other components of computing platform 600. I/O devices may include, but not be limited to, a user interface 610. User interface 610 may include devices (not shown) such as a display element, touchpad, keyboard, mouse, and speaker, etc. I/O system 608 may include a graphics subsystem configured to perform processing of images for rendering on a display element. Graphics subsystem may be a graphics processing unit or a visual processing unit (VPU), for example. An analog or digital interface may be used to communicatively couple graphics subsystem and the display element. For example, the interface may be any of a high-definition multimedia interface (HDMI), DisplayPort, wireless HDMI, and/or any other suitable interface using wireless high definition compliant techniques. In some embodiments, the graphics subsystem could be integrated into processor 602 or any chipset of computing platform 600.

It will be appreciated that in some embodiments, the various components of the computing platform 600 may be combined or integrated in a system-on-a-chip (SoC) architecture. In some embodiments, the components may be hardware components, firmware components, software components or any suitable combination of hardware, firmware or software.

In various embodiments, computing platform 600 may be implemented as a wireless system, a wired system, or a combination of both. When implemented as a wireless system, computing platform 600 may include components and interfaces suitable for communicating over a wireless shared media, such as one or more antennae, transmitters, receivers, transceivers, amplifiers, filters, control logic, and so forth. An example of wireless shared media may include portions of a wireless spectrum, such as the radio frequency spectrum and so forth. When implemented as a wired system, computing platform 600 may include components and interfaces suitable for communicating over wired communications media, such as input/output adapters, physical connectors to connect the input/output adaptor with a corresponding wired communications medium, a network interface card (NIC), disc controller, video controller, audio controller, and so forth. Examples of wired communications media may include a wire, cable metal leads, printed circuit board (PCB), backplane, switch fabric, semiconductor material, twisted pair wire, coaxial cable, fiber optics, and so forth.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical quantities within the registers, memory units, or other such information storage transmission or displays of the computer system. The embodiments are not limited in this context.

The terms “circuit” or “circuitry,” as used in any embodiment herein, may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system on-chip (SoC), desktop computers, laptop computers, tablet computers, servers, smart phones, etc. Other embodiments may be implemented as software executed by a programmable control device. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Various embodiments may be implemented using hardware elements, software elements, or a combination of both. Examples of hardware elements may include processors, microprocessors, circuits, circuit elements (for example, transistors, resistors, capacitors, inductors, and so forth), integrated circuits, ASICs, programmable logic devices, digital signal processors, FPGAs, GPUs, logic gates, registers, semiconductor devices, chips, microchips, chipsets, and so forth. Examples of software may include software components, programs, applications, computer programs, application programs, system programs, machine programs, operating system software, middleware, firmware, software modules, routines, subroutines, functions, methods, procedures, software interfaces, application program interfaces, instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power level, heat tolerances, processing cycle budget, input data rates, output data rates, memory resources, data bus speeds, and other design or performance constraints.

### Further Example Embodiments

The following examples pertain to further embodiments, from which numerous permutations and configurations will be apparent.

Example 1 is an image sensor that includes a semiconductor substrate having a given thickness between a top surface and a bottom surface of the semiconductor substrate and a plurality of pixels arranged across the substrate. A pixel of the plurality of pixels includes a first dielectric wall arranged around a perimeter of the pixel and a second dielectric wall arranged around the perimeter of the pixel and below the first dielectric wall. The first dielectric wall extends into the semiconductor substrate at a first distance beneath the top surface of the semiconductor substrate and the second dielectric wall extends into the semiconductor substrate at a second distance above the bottom surface of the semiconductor substrate. A sum of the first distance and the second distance is equal to the given thickness of the semiconductor substrate.

Example 2 includes the image sensor of Example 1, wherein the semiconductor substrate comprises a silicon substrate.

Example 3 includes the image sensor of Example 1 or 2, wherein the pixel comprises a first doped substrate portion over a second doped substrate portion, wherein the first doped substrate portion contacts a sidewall of the first dielectric wall, and wherein the second doped substrate portion contacts a sidewall of the second dielectric wall.

Example 4 includes the image sensor of Example 3, wherein the first doped substrate portion includes n-type dopants and the second doped substrate portion includes p-type dopants.

Example 5 includes the image sensor of Example 4, wherein the n-type dopants comprise arsenic and the p-type dopants comprise boron.

Example 6 includes the image sensor of any one of Examples 3-5, wherein a boundary between the first doped substrate portion and the second doped substrate portion is within 200 nm above and 200 nm below a boundary between the first dielectric wall and the second dielectric wall.

Example 7 includes the image sensor of any one of Examples 3-6, wherein the first doped substrate portion has a concentration of n-type dopants between about 1×10¹³ and 1×10¹⁴ cm⁻³ and the second doped substrate portion has a concentration of p-type dopants between about 1×10¹⁵ and 1×10¹⁶ cm⁻³.

Example 8 includes the image sensor of any one of Examples 1-7, wherein a full width across the perimeter of the pixel is between about 8 micrometers and about 12 micrometers, the full width measured from a center of the first dielectric wall on a first side of the pixel to the center of the first dielectric wall on a second side of the pixel, the second side opposing the first side.

Example 9 includes the image sensor of any one of Examples 1-8, wherein the first dielectric wall has a first width along the top surface of the semiconductor substrate between 0.3 micrometers and 1.0 micrometer, and the second dielectric wall has a second width along the bottom surface of the semiconductor substrate between 0.1 micrometers and 0.5 micrometers.

Example 10 includes the image sensor of any one of Examples 1-9, wherein the first dielectric wall and the second dielectric wall each comprise silicon and oxygen.

Example 11 includes the image sensor of any one of Examples 1-10, further comprising a first dielectric layer on a top surface of the semiconductor substrate and a second dielectric layer on a bottom surface of the semiconductor substrate.

Example 12 includes the image sensor of any one of Examples 1-11, wherein the first distance is substantially equal to the second distance.

Example 13 includes the image sensor of any one of Examples 1-12, wherein the given thickness of the semiconductor substrate is between 10 micrometers and 20 micrometers.

Example 14 is an image sensor that includes a pixel array having at least one column of addressable pixels, a column amplifier coupled to the at least one column of addressable pixels, an analog-to-digital converter (ADC) coupled to the column amplifier, and a processor coupled to the ADC. The at least one column of addressable pixels includes a pixel that has a first dielectric wall arranged around a perimeter of the pixel and a second dielectric wall arranged around the perimeter of the pixel and below the first dielectric wall. The first dielectric wall extends into a semiconductor substrate at a first distance beneath a top surface of the semiconductor substrate and the second dielectric wall extends into the semiconductor substrate at a second distance above a bottom surface of the semiconductor substrate. A top surface of the second dielectric wall contacts a bottom surface of the first dielectric wall.

Example 15 includes the image sensor of Example 14, wherein the semiconductor substrate comprises a silicon substrate.

Example 16 includes the image sensor of Example 14 or 15, wherein the pixel comprises a first doped substrate portion over a second doped substrate portion, wherein the first doped substrate portion contacts a sidewall of the first dielectric wall and the second doped substrate portion contacts a sidewall of the second dielectric wall.

Example 17 includes the image sensor of Example 16, wherein the first doped substrate portion includes n-type dopants and the second doped substrate portion includes p-type dopants.

Example 18 includes the image sensor of Example 17, wherein the n-type dopants comprise arsenic and the p-type dopants comprise boron.

Example 19 includes the image sensor of any one of Examples 16-18, wherein a boundary between the first doped substrate portion and the second doped substrate portion is within 200 nm above and 200 nm below a boundary between the first dielectric wall and the second dielectric wall.

Example 20 includes the image sensor of any one of Examples 16-19, wherein the first doped substrate portion has a concentration of n-type dopants between about 1×10¹³ and 1×10¹⁴ cm⁻3 and the second doped substrate portion has a concentration of p-type dopants between about 1×10¹⁵ and 1×10¹⁶ cm⁻3.

Example 21 includes the image sensor of any one of Examples 14-20, wherein a full width across the perimeter of the pixel is between about 8 micrometers and about 12 micrometers.

Example 22 includes the image sensor of any one of Examples 14-21, wherein the first dielectric wall has a first width along the top surface of the semiconductor substrate between 0.3 micrometers and 1.0 micrometer, and the second dielectric wall has a second width along the bottom surface of the semiconductor substrate between 0.1 micrometers and 0.5 micrometers.

Example 23 includes the image sensor of any one of Examples 14-22, wherein the first dielectric wall and the second dielectric wall each comprise silicon dioxide.

Example 24 includes the image sensor of any one of Examples 14-23, wherein the pixel further comprises a first dielectric layer on a top surface of the semiconductor substrate and a second dielectric layer on a bottom surface of the semiconductor substrate.

Example 25 includes the image sensor of any one of Examples 14-24, wherein the first distance is substantially equal to the second distance.

Example 26 includes the image sensor of any one of Examples 14-25, wherein the semiconductor substrate has a thickness between the top surface and the bottom surface of between 10 micrometers and 20 micrometers.

Example 27 is a pixel of a pixel array within a CMOS image sensor that includes a first semiconductor region having a first concentration of n-type dopants, a second semiconductor region beneath the first semiconductor region and having a second concentration of p-type dopants, a first dielectric wall arranged around a perimeter of the pixel and extending through a thickness of the first semiconductor region, and a second dielectric wall arranged around the perimeter of the pixel and extending through a thickness of the second semiconductor region. The second dielectric wall contacts the first dielectric wall.

Example 28 includes the pixel of Example 27, wherein the first and second semiconductor regions comprise silicon.

Example 29 includes the pixel of Example 27 or 28, wherein the first semiconductor region has substantially the same thickness as the second semiconductor region.

Example 30 includes the pixel of any one of Examples 27-29, wherein a total thickness of the first semiconductor region and the second semiconductor region is between about 10 micrometers and 20 micrometers.

Example 31 includes the pixel of any one of Examples 27-30, wherein the n-type dopants comprise arsenic and the p-type dopants comprise boron.

Example 32 includes the pixel of any one of Examples 27-31, wherein a boundary between the first semiconductor region and the second semiconductor region is within 200 nm above and 200 nm below a boundary between the first dielectric wall and the second dielectric wall.

Example 33 includes the pixel of any one of Examples 27-32, wherein the first concentration of n-type dopants is between about 1×10¹³ and 1×10¹⁴ cm⁻³ and the second concentration of p-type dopants is between about 1×10¹⁵ and 1×10¹⁶ cm⁻³.

Example 34 includes the pixel of any one of Examples 27-33, wherein a full width across the perimeter of the pixel is between about 8 micrometers and about 12 micrometers.

Example 35 includes the pixel of any one of Examples 27-34, wherein the first dielectric wall has a largest width between about 0.3 micrometers and 1.0 micrometer, and the second dielectric wall has a largest width between about 0.1 micrometers and 0.5micrometers.

Example 36 includes the pixel of any one of Examples 27-35, wherein the first dielectric wall and the second dielectric wall each comprise silicon dioxide.

Example 37 includes the pixel of any one of Examples 27-36, wherein a top surface of the second dielectric wall contacts a bottom surface of the first dielectric wall.

Numerous specific details have been set forth herein to provide a thorough understanding of the embodiments. It will be understood by an ordinarily-skilled artisan, however, that the embodiments may be practiced without these specific details. In other instances, well known operations, components and circuits have not been described in detail so as not to obscure the embodiments. It can be appreciated that the specific structural and functional details disclosed herein may be representative and do not necessarily limit the scope of the embodiments. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

What is claimed is:

1. An image sensor, comprising:
a semiconductor substrate having a given thickness between a top surface and a bottom surface of the semiconductor substrate; and
a plurality of pixels arranged across the substrate, wherein a pixel of the plurality of pixels comprises
a first dielectric wall arranged around a perimeter of the pixel and extending into the semiconductor substrate at a first distance from the top surface of the semiconductor substrate, and
a second dielectric wall arranged around the perimeter of the pixel and below the first dielectric wall, the second dielectric wall extending into the semiconductor substrate at a second distance from the bottom surface of the semiconductor substrate, wherein a sum of the first distance and the second distance is equal to the given thickness of the semiconductor substrate.

2. The image sensor of claim 1, wherein the pixel comprises a first doped substrate portion over a second doped substrate portion, wherein the first doped substrate portion contacts a sidewall of the first dielectric wall, and wherein the second doped substrate portion contacts a sidewall of the second dielectric wall.

3. The image sensor of claim 2, wherein the first doped substrate portion includes n-type dopants and the second doped substrate portion includes p-type dopants.

4. The image sensor of claim 2, wherein the first doped substrate portion has a concentration of n-type dopants between about 1×10¹³ and 1×10¹⁴ cm⁻³ and the second doped substrate portion has a concentration of p-type dopants between about 1×10¹⁵ and 1×10¹⁶ cm⁻³.

5. The image sensor of claim 1, wherein the first dielectric wall has a first width along the top surface of the semiconductor substrate between 0.3 micrometers and 1.0 micrometer, and the second dielectric wall has a second width along the bottom surface of the semiconductor substrate between 0.1 micrometers and 0.5 micrometers.

6. The image sensor of claim 1, wherein the first distance is substantially equal to the second distance.

7. The image sensor of claim 1, wherein the given thickness of the semiconductor substrate is between 10 micrometers and 20 micrometers.

8. An image sensor, comprising:
a pixel array having at least one column of addressable pixels;
a column amplifier coupled to the at least one column of addressable pixels;
an analog-to-digital converter (ADC) coupled to the column amplifier; and
a processor coupled to the ADC;
wherein the at least one column of addressable pixels includes a pixel that comprises
a first dielectric wall arranged around a perimeter of the pixel and extending into a semiconductor substrate at a first distance from a top surface of the semiconductor substrate, and
a second dielectric wall arranged around the perimeter of the pixel and below the first dielectric wall, the second dielectric wall extending into the semiconductor substrate at a second distance from a bottom surface of the semiconductor substrate, wherein a top surface of the second dielectric wall contacts a bottom surface of the first dielectric wall.

9. The image sensor of claim 8, wherein the pixel comprises a first doped substrate portion over a second doped substrate portion, wherein the first doped substrate portion contacts a sidewall of the first dielectric wall and the second doped substrate portion contacts a sidewall of the second dielectric wall.

10. The image sensor of claim 9, wherein the first doped substrate portion includes n-type dopants and the second doped substrate portion includes p-type dopants.

11. The image sensor of claim 9, wherein the first doped substrate portion has a concentration of n-type dopants between about 1×10¹³ and 1×10¹⁴ cm⁻³ and the second doped substrate portion has a concentration of p-type dopants between about 1×10¹⁵ and 1×10¹⁶ cm⁻³.

12. The image sensor of claim 8, wherein the first distance is substantially equal to the second distance.

13. The image sensor of claim 8, wherein the semiconductor substrate has a thickness between the top surface and the bottom surface of between 10 micrometers and 20 micrometers.

14. A pixel of a pixel array within a CMOS image sensor, the pixel comprising:
a first semiconductor region having a first concentration of n-type dopants;
a second semiconductor region beneath the first semiconductor region, the second semiconductor region having a second concentration of p-type dopants;
a first dielectric wall arranged around a perimeter of the pixel and extending through a thickness of the first semiconductor region; and
a second dielectric wall arranged around the perimeter of the pixel and extending through a thickness of the second semiconductor region, wherein the second dielectric wall contacts the first dielectric wall.

15. The pixel of claim 14, wherein the first semiconductor region has substantially the same thickness as the second semiconductor region.

16. The pixel of claim 14, wherein a total thickness of the first semiconductor region and the second semiconductor region is between about 10 micrometers and 20 micrometers.

17. The pixel of claim 14, wherein a boundary between the first semiconductor region and the second semiconductor region is within 200 nm above and 200 nm below a boundary between the first dielectric wall and the second dielectric wall.

18. The pixel of claim 14, wherein a full width across the perimeter of the pixel is between about 8 micrometers and about 12 micrometers.

19. The pixel of claim 14, wherein the first dielectric wall has a largest width between about 0.3 micrometers and 1.0 micrometer, and the second dielectric wall has a largest width between about 0.1 micrometers and 0.5 micrometers.

20. The pixel of claim 14, wherein a top surface of the second dielectric wall contacts a bottom surface of the first dielectric wall.
